(19) United States
(12) Patent Application Publication
(10) Pub. No.: US 2008/0128852 A1
(43) Pub. Date: Jun. 5, 2008

(54) Semiconductor apparatus and method of producing the same

(75) Inventor: Yuki Tasaka, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/902,193

(22) Filed: Sep. 19, 2007

(30) Foreign Application Priority Data
Sep. 21, 2006 (JP) 2006-255347

(51) Int. Cl. H01L 29/02

(52) U.S. Cl. 257/506; 257/E29.002

(57) ABSTRACT

In a semiconductor apparatus, first diffusion layers in a first diffusion layer region have an upwardly curved shape formed by upwardly protruding a surface of the silicon substrate while second diffusion layers of a second diffusion layer region have a flat shape as compared with the first diffusion layer region. The semiconductor apparatus includes a silicon substrate, the first diffusion layer region formed on the silicon substrate and including the first diffusion layers separated by a device isolation region, and the second diffusion layer region which is formed on the silicon substrate at a position different from that of the first diffusion layer region and includes the second diffusion layers.

This application claims the benefit of priority from Japanese patent application No. 2006-255347, filed on Sep. 21, 2006, the disclosure of which is incorporated herein by reference in its entirety.

### BACKGROUND OF THE INVENTION

This invention relates to a semiconductor apparatus and a method of producing the same and, in particular, to a semiconductor memory apparatus such as DRAM (Dynamic Random Access Memory) and a method of producing the same,

In recent years, a semiconductor apparatus is more and more miniaturized. Following such miniaturization, a device forming the semiconductor apparatus is also reduced in size. Accordingly, an active region (diffusion layer region) insulated and isolated for each individual transistor by the use of a device isolation region (field region) such as STI (Shallow Trench Isolation) is reduced in size. This results in a decrease in gate width of the transistor, which is determined by the width of the active region. Under the influence of the decrease in gate width, an on current (Ion) of the transistor is disadvantageously reduced.

In particular, in a semiconductor memory apparatus having a memory cell region, an active region forming a transistor in the memory cell region is designed to be smaller in size than that forming a transistor in a peripheral circuit region. Therefore, the influence of the reduction in size is significant. The decrease in on current of the transistor is particularly remarkable in the memory cell region.

Referring to FIGS. 1A to 1C, a semiconductor apparatus of the type will be described in detail.

FIG. 1A is a plan view showing a device isolation region 1 and a plurality of active regions (diffusion layer regions) 2 of a related DRAM cell structure. FIG. 1B is a sectional view taken along a line IB-IB in FIG. 1A. For the purpose of comparison, FIG. 1C shows a structure obtained by simply scaling down the structure in FIG. 1B.

In order to facilitate an understanding, FIG. 1A shows a simplified illustration. In the cell region of an actual DRAM, repetitive patterns of the diffusion layer regions 2 of the same shape are regularly arranged.

In case where transistors forming the semiconductor apparatus are simply scaled down, a width 14 of each active region (diffusion region) 2 separated by the device isolation region 1 is gradually narrowed as is obvious from comparison between FIGS. 1B and 1C. When the width 14 of the active region 2 is narrowed, an on current (ion) of the transistor formed in the active region 2 is disadvantageously decreased.

Japanese Unexamined Patent Application Publication (JP-A) No. 2002-33476 (Patent Document 1) discloses a technique for preventing a decrease in on current of a transistor without enlarging a chip area. Specifically, Patent Document 1 proposes a structure in which a gate electrode covers not only a device region but also a part of a side surface of a trench adjacent to the device region and a gate oxide film is arranged under the gate electrode. With this structure, the gate electrode has irregularities resulting from a step between the device region and a trench isolation oxide film formed in the trench. This is equivalent to an enlargement of the gate electrode. Further, Patent Document 1 discloses that convergence of a fringing field from the gate electrode is suppressed by providing an upper edge portion of an active region with a round portion having an arcuate cross section and a radius of curvature of about 30 nm.

Japanese Patent Publication (JP-B) No. 3203048 (Patent Document 2) discloses a semiconductor device and a method of producing the same, which are capable of suppressing a leak current at an edge portion of a trench and of reducing a contact resistance. For this purpose, Patent Document 2 proposes a structure in which each of the edge portion of the trench and source and drain portions has a curvature. Thus, each of the source and drain portions has a dome-like structure with a curvature in a gate width direction so that a contact region on the source and the drain portions can be increased in area and the contact resistance can be reduced.

Further, Patent Document 2 discloses a technique of making an active layer to form the source and drain portions have a curvature. Specifically, in the state where a silicon nitride film is left in a region to serve as each of the source and drain portions, a field oxide film is formed so that the silicon nitride film is surrounded by the field oxide film in a dome-like shape. Thereafter, the silicon nitride film and the field oxide film are removed. Thus, the active layer of a dome-like structure is formed.

In Patent Documents 1 and 2, attention is focused only upon a structure of a single kind of transistor formed in a semiconductor apparatus. In other words, Patent Documents 1 and 2 do not clarify a structure of a whole of an actual semiconductor apparatus, in particular, an actual DRAM. In the actual semiconductor apparatus, such as the DRAM, including a memory cell region and a peripheral circuit region, the memory cell region and the peripheral circuit region must have structures different from each other. For example, in the memory cell region and the peripheral circuit region, MOS transistors different in size, material of an insulating film, and characteristics from each other may be arranged. In the peripheral circuit region, an alignment mark may be arranged.

Patent Documents 1 and 2 do not disclose the actual semiconductor apparatus which requires different considerations for the memory cell region and the peripheral circuit region. Specifically, Patent Documents 1 and 2 do not disclose a method of easily forming different MOS transistors in the memory cell region and the peripheral circuit region. Further, Patent Documents 1 and 2 do not clarify simultaneous formation of different circuits required for the memory cell region and the peripheral circuit region.

### SUMMARY OF THE INVENTION

It is therefore an object of this invention to provide a semiconductor apparatus having different kinds of circuits formed in a memory cell region and a peripheral circuit region, which can be prevented from a decrease in on current of a transistor in the memory cell region.

It is another object of this invention to provide a method of producing a semiconductor apparatus, which is capable of easily forming different kinds of transistors arranged in a memory cell region and a peripheral circuit region.

It is still another object of this invention to provide a method of producing a semiconductor apparatus, which is capable of simultaneously forming different kinds of circuits in a memory cell region and a peripheral circuit region different in circuit structure.

Semiconductor apparatuses according to this invention and methods according to this invention are as follows:

(1) A semiconductor apparatus comprising a silicon substrate, a first diffusion layer region formed on the silicon substrate and comprising a plurality of diffusion layers separated by a device isolation region, and a second diffusion layer region formed on the silicon substrate at a position different from that of the first diffusion layer region and comprising a plurality of diffusion layers, wherein the diffusion layers in the first diffusion layer region have an upwardly curved shape formed by upwardly protruding a surface of the silicon substrate, the diffusion layers of the second diffusion layer region have a flat shape as compared with the first diffusion layer region.

(2) The semiconductor apparatus as described in (1), comprising a memory cell region in which a plurality of the first diffusion layer regions of the same shape are regularly arranged.

(3) The semiconductor apparatus as described in (1), wherein the second diffusion layer region is a peripheral circuit region comprising a region provided with scribe lines.

(4) A semiconductor apparatus comprising a silicon substrate, a first diffusion layer region formed on the silicon substrate and comprising a plurality of diffusion layers separated by a device isolation region, and a second diffusion layer region formed on the silicon substrate at a position different from that of the first diffusion layer region and comprising a plurality of diffusion layers, wherein the diffusion layers in both of the first and the second diffusion layer regions have an upwardly curved shape formed by upwardly protruding a surface of the silicon substrate, the first diffusion layer region comprising the diffusion layers smaller in radius of curvature of the surface of the silicon substrate than the diffusion layers forming the second diffusion layer region.

(5) The semiconductor apparatus as described in (1) or (4), further comprising a first gate insulating film formed on the first diffusion layer region and a second gate insulating film formed on the second diffusion layer region, the first and the second gate insulating films being different in thickness.

(6) The semiconductor apparatus as described in (1) or (4), further comprising gate electrodes formed on the first and the second diffusion layer regions through gate insulating films, respectively.

(7) A semiconductor apparatus comprising a silicon substrate, a first diffusion layer region formed on the silicon substrate and comprising a plurality of diffusion layers separated by a device isolation region, and a second diffusion layer region formed on the silicon substrate at a position different from that of the first diffusion layer region and comprising a plurality of diffusion layers, wherein the first diffusion layer region is provided with a second silicon layer formed in contact with a surface of a first silicon layer forming the silicon substrate, the second silicon layer having a surface of an upwardly curved shape.

(8) The semiconductor apparatus as described in (7), wherein the second diffusion layer region is flat as compared with the surface of the second silicon layer.

(9) A semiconductor apparatus comprising a silicon substrate, and first and second diffusion layers formed on the silicon substrate, separated by a device isolation region, and having first and second widths, respectively, wherein the second width is greater than the first width, each of the first and the second diffusion layers having an upwardly curved shape formed by upwardly protruding a surface of the silicon substrate, the first diffusion layer being smaller in radius of curvature than the second diffusion layer, the radius of curvature representing a curved shape of the surface of the silicon substrate.

(10) A method of producing a semiconductor apparatus, comprising the steps of forming a device isolation region on a silicon substrate to separate a plurality of diffusion layer regions, forming an insulating film on a surface of each of the diffusion layer regions, partly removing the insulating film to expose a surface of the silicon substrate at a part of each of the diffusion layer regions, curving an exposed part of the surface of the silicon substrate into a round shape by heat treating the silicon substrate in a high-temperature hydrogen atmosphere.

(11) The method as described in (10), wherein the step of curving is a step of curving the silicon substrate upward depending upon the size of the exposed part of the surface of the silicon substrate.

(12) The method as described in (10), wherein the step of curving the surface of the silicon substrate is followed by the steps of removing a whole of the insulating film, forming a gate insulating film throughout an entire surface of the silicon substrate, and forming a gate electrode on the gate insulating film.

(13) The method as described in (10), wherein the hydrogen atmosphere has a temperature between 800° C. and 1000° C.

In this invention, the surface of the diffusion layer region in the memory cell region is curved by a simple technique easily applicable to production of semiconductor products. In this manner, it is possible to prevent a decrease in on current (ion) of the transistor used in the memory cell region. Specifically, in case where the on current of the transistor used in the memory cell region is improved according to this invention, it is possible to reduce the size of the transistor in the memory cell region in which each active region is originally designed to have a narrow width and a large number of active regions are arranged. Therefore, the effect of reduction in size is great as compared with the case where the size of the transistor in the peripheral circuit region is reduced. Further, according to this invention, it is possible to individually and simultaneously form different kinds of circuits having different characteristics required for the memory cell region and the peripheral circuit region.

### BRIEF DESCRIPTION OF THE DRAWING

FIG. 1A is a plan view showing a device isolation region and active regions (diffusion layer regions) of a related DRAM cell structure;

FIG. 1B is a sectional view taken along a line IB-IB in FIG. 1A;

FIG. 1C is a sectional view showing a scaled-down structure;

FIG. 2A is a sectional view of a memory cell region according to this invention;

FIG. 2B is a sectional view of a peripheral circuit region according to this invention;

FIGS. 3A to 3D are sectional views for describing a sequence of steps in a method according to a first embodiment of this invention, (a) showing the memory cell region, (b) showing the peripheral circuit region;

FIG. 4A is a sectional view of the memory cell region obtained by the method according to the first embodiment:

FIG. 4B is a sectional view of the peripheral circuit region corresponding to FIG. 4A;

FIGS. 5A to 5E are sectional views for describing a sequence of steps in a method according to a second embodiment of this invention, (a) showing a thin film part of a gate insulating film, (b) showing a thick film part of the gate insulating film;

FIGS. 6A to 6E are sectional views for describing a sequence of steps in a method according to a third embodiment of this invention, (a) showing a thin film part of a gate insulating film, (b) showing a thick film part of the gate insulating film;

FIGS. 7A to 7F are sectional views for describing a sequence of steps in a method according to a fourth embodiment of this invention, (a) showing a thin film part of a gate insulating film, (b) showing a thick film part of the gate insulating film; and

FIGS. 8A to 8F are sectional views for describing a sequence of steps in a method according to a fifth embodiment of this invention, (a) showing a thin film part of a gate insulating film, (b) showing a thick film part of the gate insulating film.

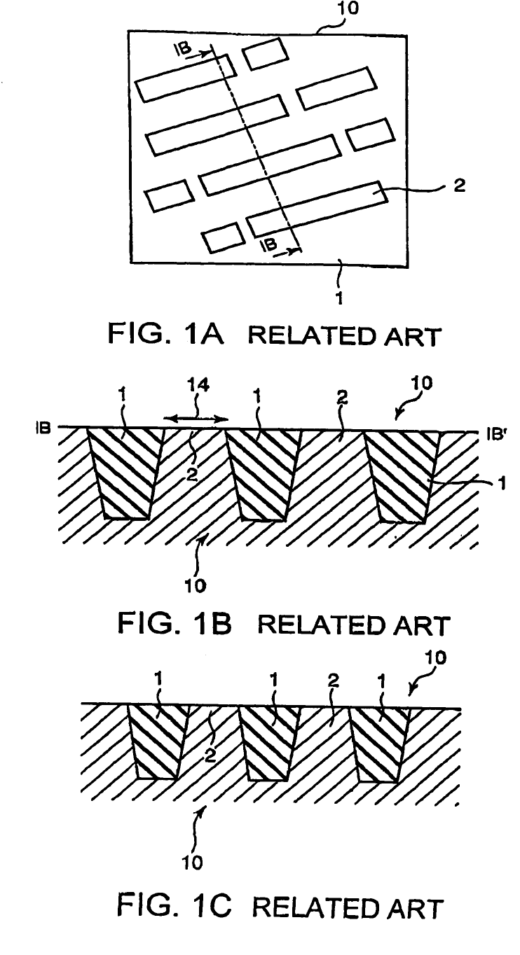

### DESCRIPTION OF THE EXEMPLARY EMBODIMENTS

Now, several exemplary embodiments of this invention will be described with reference to the drawing.

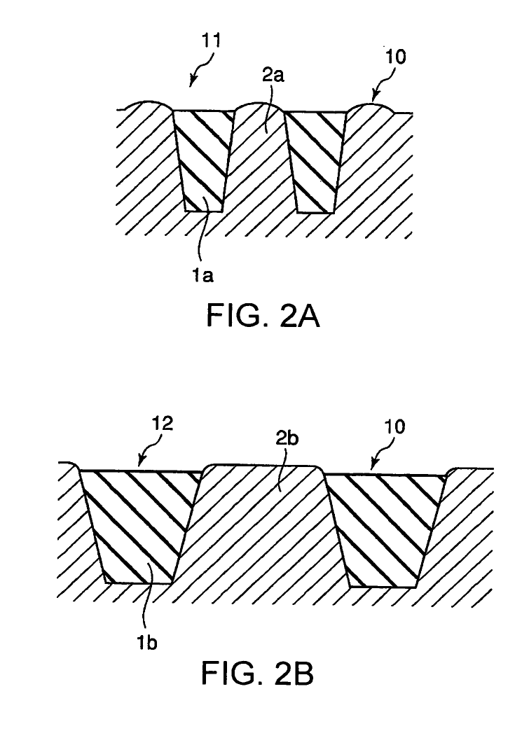

FIG. 2A is a sectional view of a memory cell region 11 according to this invention while FIG. 2B is a sectional view of a peripheral circuit region 12. The memory cell region 11 and the peripheral circuit region 12 are formed in different areas of a single semiconductor chip. Referring to FIG. 2A, the memory cell region 11 has a device isolation region 1a formed around a plurality of diffusion layer regions (active regions) 2a by the use of STI. Referring to FIG. 2B, the peripheral circuit region 12 has a device isolation region 1b formed around a plurality of diffusion layer regions (active regions) 2b by the use of STI. As is obvious from FIGS. 2A and 2B, each diffusion layer region 2a in the memory cell region 11 is narrower in width than each diffusion layer region 2b in the peripheral circuit region 12.

A method according to this invention is characterized by rounding, i.e., curving a surface of each of the diffusion layer regions 2a and 2b by H₂ baking. It has been found out that, in case where the surface of the diffusion layer region is curved by H₂ baking, curving rates of active regions of transistors in the memory cell region 11 and the peripheral circuit region 12 can be remarkably different from each other. Specifically, the surface of the diffusion layer region 2a in the memory cell region 11 is largely curved as compared with the surface of the diffusion layer region 2b in the peripheral circuit region 12. That is, a greater curving rate (curvature) can be obtained in the memory cell region 11 as compared with the peripheral circuit region 12. Therefore, an on current ion of the transistor in the memory cell region 11 can efficiently be increased. Thus, differently curved shapes are obtained because the diffusion layer region 2a in the memory cell region 11 is narrower in width than the diffusion layer region 2b in the peripheral circuit region 12.

This invention resides in that, by the use of the relationship between H₂ baking and the size of the diffusion layer region to be baked, diffusion layer regions having surfaces with different curving rates (curvatures) are formed in a single chip. Specifically, in this invention, an on current of the transistor in the memory cell region can be improved by making the surface of the diffusion layer region 2a in the memory cell region 11 have a curvature greater than that of the surface of the diffusion layer region 2b in the peripheral circuit region 12. Further, by flattening the surface of the diffusion layer region 2b in the peripheral circuit region 12 as compared with the surface of the diffusion layer region 2a in the memory cell region 11, it is possible to provide the peripheral circuit region 12 with a transistor or a wiring of a structure appropriate to the peripheral circuit region 12.

### EMBODIMENTS

Now, a method of producing a semiconductor apparatus according to this invention will be described in connection with several embodiments. In each of the embodiments, in presence of an oxide film, a Si surface is not changed and, therefore, is not curved even when H₂ baking is carried out.

### FirstT Embodiment

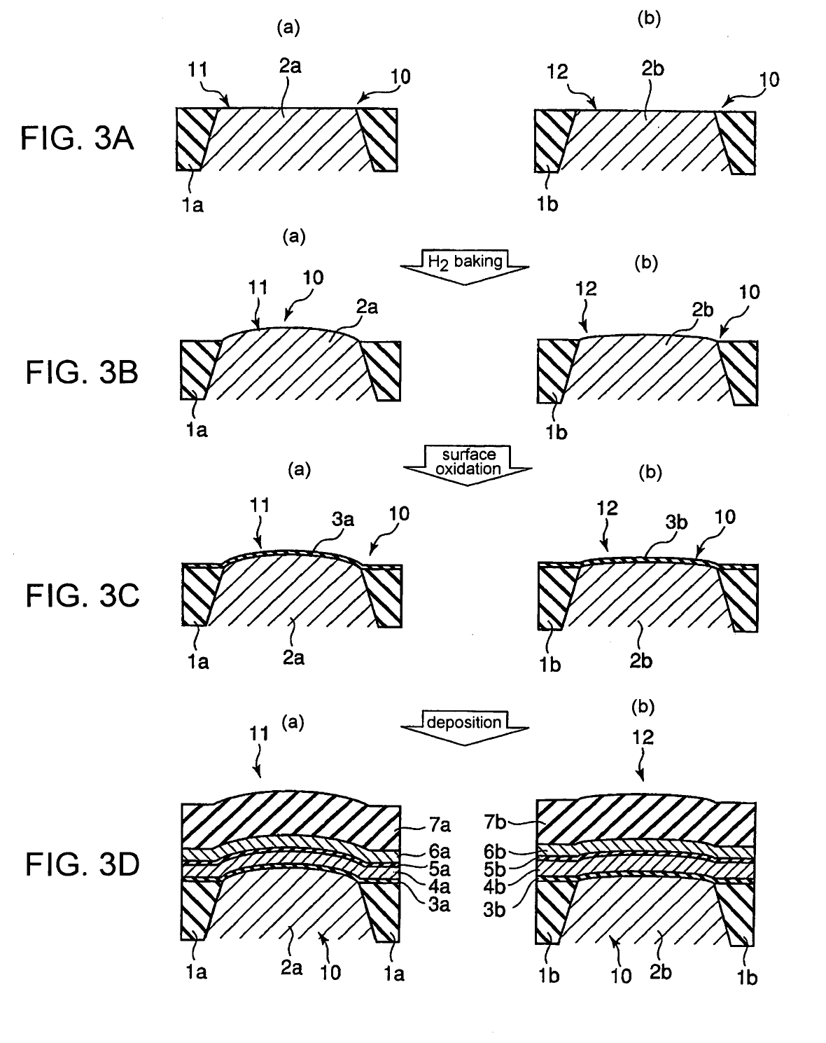

Referring to FIGS. 3A to 3D, description will be made of a method of producing a semiconductor apparatus according to a first embodiment of this invention. FIGS. 3A to 3D show a sequence of steps.

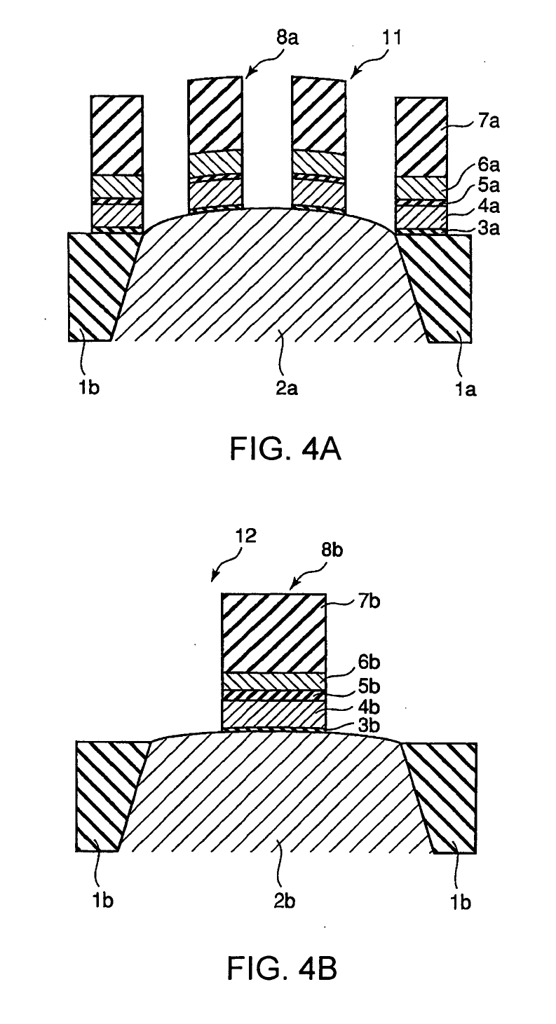

In FIGS. 3A to 3D, (a) and (b) show the memory cell region 11 and the peripheral circuit region 12, respectively. FIGS. 4A and 4B show the memory cell region 11 and the peripheral circuit region 12, respectively, after completion of the steps in FIGS. 3A to 3D. For convenience of illustration, the memory cell region 11 and the peripheral circuit region 12 are shown in the same scale. Actually, however, like in FIGS. 2A and 2B, the peripheral circuit region 12 is wider in width than the memory cell region 11.

At first, as illustrated in FIG. 3A, device isolation regions 1a and 1b are formed on a semiconductor substrate made of silicon in the memory cell region 11 and the peripheral circuit region 12, respectively. Remaining parts except the device isolation regions 1a and 1b are diffusion layer regions (i.e., active regions) 2a and 2b.

Next, in the state where silicon surfaces of the diffusion layer regions 2a and 2b are exposed by wet etching, heat treatment (baking) is carried out in a hydrogen (H₂) atmosphere at a temperature between 800° C. and 1000° C.

As illustrated in FIG. 3B, silicon atoms exposed to the hydrogen atmosphere at a high temperature migrate so that each of the diffusion layer regions 2a and 2b has a round shape protruding upward. At this time, the round shape has a higher degree of roundness, i.e., is largely curved as the width of the diffusion layer regions 2a and 2b is narrower. Therefore, the diffusion layer region 2a in the memory cell region 11 shown in (a) of FIG. 3B has a shape largely curved upward because the width of the diffusion layer region 2a is narrowest. Thus, in the first embodiment, the diffusion layer regions 2a and 2b having different curving rates can simultaneously formed by the same H₂ baking.

On the other hand, as illustrated in (b) of FIG. 3B, the diffusion layer region 2b in the peripheral circuit region 12 has a width sufficiently wider than that of the diffusion layer region 2a in the memory cell region 11. Therefore, the curving rate of the diffusion layer region 2b in the peripheral circuit region 12 is small as compared with the diffusion layer region 2a in the memory cell region 11 although the diffusion layer region 2b is deformed in a round shape. Thus, the diffusion layer region 2a in the memory cell region 11 has a curvature greater than that of the diffusion layer region 2b in the peripheral circuit region 12. In other words, the radius of curvature of the surface of the diffusion layer region 2a in the memory cell region 11 is smaller than that of the surface of the diffusion layer region 2b in the peripheral circuit region 12.

Next, as illustrated in FIG. 3C, gate insulating films 3a and 3b are formed on the diffusion layer regions 2a and 2b by a known technique, respectively.

As the gate insulating films 3a and 3b, a silicon oxide film (SiO₂), a laminated film comprising a silicon oxide film and a nitride film (Si₃N₄), or any other insulating film having a high dielectric constant may be used.

Next, as illustrated in FIG. 3D, phosphorus doped polysilicon (DOPOS) films 4a and 4b, tungsten nitride (WN) films 5a and 5b, tungsten (W) films 6a and 6b, and plasma nitride (p-Si₃N₄) films 7a and 7b are successively deposited to form layers to become gate electrodes.

At this time, a step of depositing tungsten silicide (WSI) films between the polysilicon films 4a and 4b and the WN films 5a and 5b may be added.

The plasma nitride film 7a as a topmost layer serves as a protective film when a contact hole is formed adjacent the gate electrode in the memory cell region 11 in a later step. The plasma nitride film 7a may be replaced by any other appropriate insulating film.

The tungsten films 6a and 6b may be replaced by other metal films. Referring to FIGS. 3A to 3D, description has been made about the case where the gate electrode comprises a laminated structure of a plurality of kinds of films. Alternatively, the gate electrode may comprise a single kind of conductive film.

Next, as shown in FIGS. 4A and 4B, patterning is carried out by the use of photoresists (not shown) into desired shapes so that gate electrodes 8a and 8b are formed in the diffusion layer regions 2a and 2b, respectively.

Subsequently, source and drain regions are formed by a known technique. Then, transistors are completed. In necessary, a sidewall may be formed on a side surface of a LDD (Lightly Doped Drain) region or the gate electrode.

FIG. 4 shows sections in a direction perpendicular to a gate electrode wiring. It is noted that the diffusion layer region is similarly curved also in a section parallel to the gate electrode wiring. As a result, the effect equivalent to enlargement of a gate width of the transistor is obtained. As compared with the case where the diffusion layer region is not curved, the on current ion is increased.

### Second Embodiment

In a product such as a DRAM, a plurality of levels of power supply voltages are used inside the product in order to improve characteristics. In this case, it is general to provide a plurality of kinds of gate insulating films of transistors depending upon the power supply voltages to be used. Hereinafter, description will be made of the case where this invention is applied to a semiconductor apparatus having two kinds of gate insulating film thicknesses (a thin film part and a thick film part). A memory cell region comprises the thick film part. A peripheral circuit region includes the thin film part and the thick film part. It will readily be understood that the cell region may comprise the thin film part.

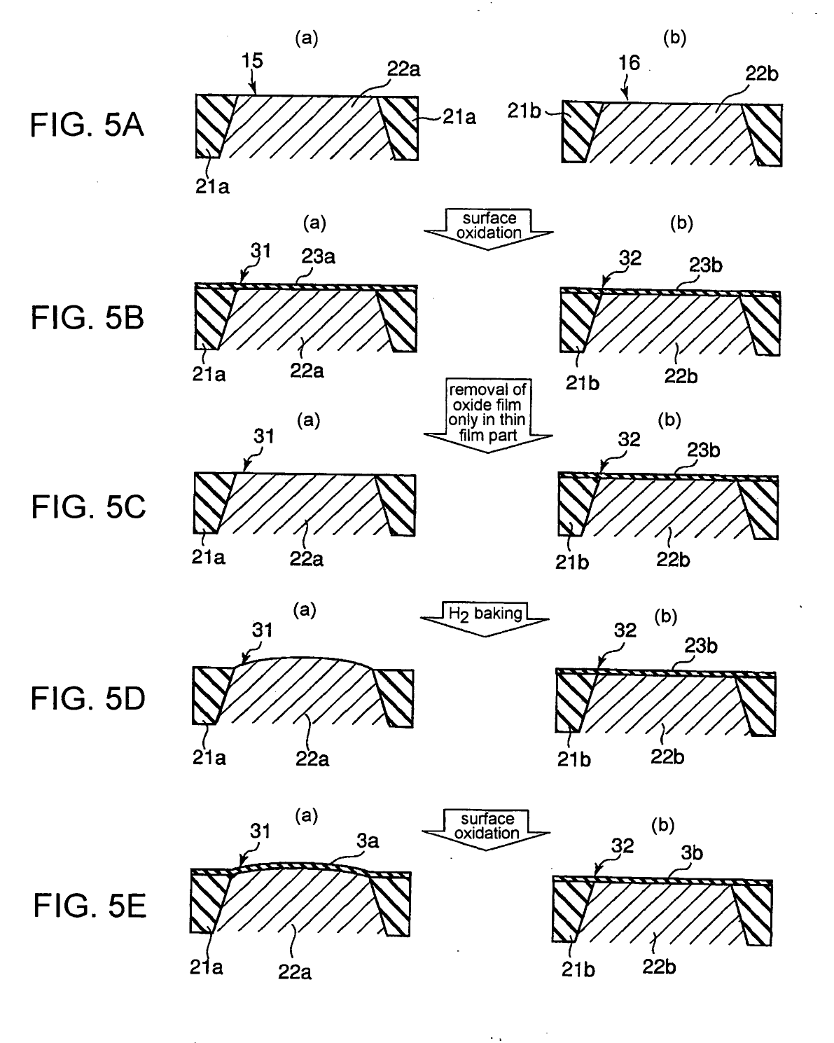

In FIGS. 5A to 5E, (a) shows a thin film part 15 of a gate insulating film to which a method according to a second embodiment of this invention is applied. (b) shows a thick film part 16 of the gate insulating film corresponding to (a).

At first, as illustrated in FIG. 5A, device isolation regions 21a and 21b are formed on a semiconductor substrate made of silicon by the use of STI as a known technique, respectively. Remaining parts except the device isolation regions 21a and 21b are diffusion layer regions 22a and 22b.

Next, as illustrated in FIG. 5B, first gate insulating films 23a and 23b are formed on the diffusion regions 22a and 22b by a known technique, respectively.

As illustrated in (a) of FIG. 5C, the first gate insulating film 23a is removed by wet etching only in the thin film part 15 to expose the diffusion layer region 22a. In this state, baking is carried out in a hydrogen (H₂) atmosphere at a temperature between 800° C. and 1000° C. On the other hand, as illustrated in (b) in FIG. 5C, the first gate insulating film 23b in the thick part 16 is not removed. As a result, the diffusion layer region 22b is kept covered with the first gate insulating film 23b.

Next, as illustrated in (a) of FIG. 5D, silicon atoms exposed to the hydrogen atmosphere at a high temperature migrate so that the diffusion layer region 22a has a round shape protruding upward.

At this time, as illustrated in (b) of FIG. 5D, the diffusion layer region 22b in the thick film part 16 is covered with the first gate insulating film 23b. Therefore, the diffusion layer region 22b is not curved but maintains a flat state. As a result, the diffusion layer region 22b in the thick film part 16 has a surface which is flat and has a large radius of curvature as compared with a surface of the diffusion layer region 22a in the thin film part 15.

Next, as illustrated in FIG. 5E, second gate insulating films 3a and 3b are formed, At this time, in the thin film part 15 illustrated in (a) of FIG. 5E, the second gate insulating film 3a is formed directly on the diffusion layer regions 22a. On the other hand, in the thick film part 16 shown in (b) of FIG. 5E, the second gate insulating film is formed on the first gate insulating film 23b to form a thick gate insulating film 3b. Thus, by appropriately selecting the thickness of the first gate insulating films 23a and 23b, the thicknesses of the thin and thick gate insulating films 3a and 3b finally obtained have desired values.

As the first gate insulating films 23a and 23b and the second gate insulating films 3a and 3b, a silicon oxide film (SiO₂), a laminated film comprising a silicon oxide film and a nitride film (Si₃N₄), or any other insulating film having a high dielectric constant may be used.

Subsequent steps are similar to those in the first embodiment and will not be described herein.

As described above, in the second embodiment, the diffusion layer region of the transistor in the thin film part alone can be curved. Generally, a transistor comprising a thin gate insulating film is used in a portion requiring a high on current. According to this invention, it is possible to further increase the on current of the transistor in the thin film part. Further, no influence is given to characteristics of a transistor in the thick film part.

As will be understood from the second embodiment, it is possible to prevent the surface of the silicon substrate from being curved in an area where the thick gate insulating film 3b is formed. This means that the technique in the second embodiment can be used if it is not desired to curve the surface of the silicon substrate also in a diffusion layer region without a transistor. For example, in a scribe line region formed between semiconductor chips, i.e., in an area where cutting is performed during dicing, a diffusion layer is generally formed. Since an alignment mark or the like for use in patterning is formed in this area, it is desired not to curve a silicon substrate. Therefore, by forming a thick gate insulating film on the diffusion layer in the scribe line region so that the silicon substrate in the scribe line region is not curved while the silicon substrate is curved in a remaining diffusion layer region within the chip.

### Third Embodiment

A third embodiment of this invention is a modification of the first embodiment. In the third embodiment, H₂ baking is performed after a gate insulating film is removed only from a memory cell region.

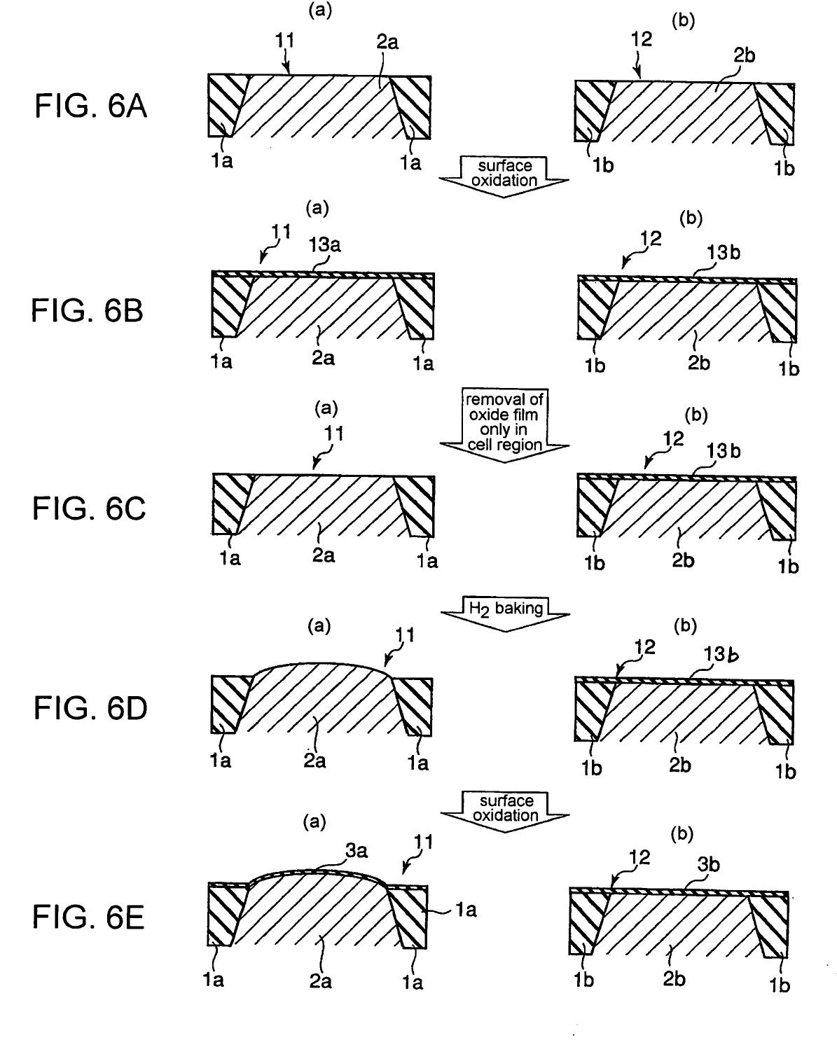

In FIGS. 6A to 6E, (a) shows a thin film part of a gate insulating film to which a method according to the third embodiment is applied. (b) shows a thick film part of the gate insulating film corresponding to (a).

At first, as illustrated in FIG. 6A, device isolation regions 1a and 1b are formed on a semiconductor substrate made of silicon by the use of STI as a known technique, respectively. Remaining parts except the device isolation regions 1a and 1b are diffusion layer regions 2a and 2b.

Next, as illustrated in FIG. 6B, gate insulating films 13a and 13b are formed on the diffusion regions 2a and 2b by a known technique, respectively.

As illustrated in (a) of FIG. 6C, the gate insulating film 13a is removed by wet etching only in a memory cell region 11 to expose the diffusion layer region 2a. On the other hand, as illustrated in (b) in FIG. 6C, the gate insulating film 13b in a peripheral circuit region 12 is not removed. As a result, the diffusion layer region 2b is kept covered with the gate insulating film 13b. In the state where the diffusion layer region 2a is exposed and the diffusion layer region 2b is covered with the gate insulating film 13b, baking is carried out in a hydrogen (H₂) atmosphere at a temperature between 800° C. and 1000° C.

As illustrated in (a) of FIG. 6D, silicon atoms exposed to the hydrogen atmosphere at a high temperature migrate so that the diffusion layer region 2a has a round shape protruding upward. On the other hand, as illustrated in (b) of FIG. 6D, the diffusion layer region 2b covered with the gate insulating film 13b maintains a flat state.

As illustrated in (a) of FIG. 6E, a new gate insulating film 3a is formed on the diffusion layer region 2a by a known technique. As illustrated in (b) of FIG. 6E, a new gate insulating film is also formed on the gate insulating film 13b in the peripheral circuit region 12 to form a thick gate insulating film 3b.

If it is not desired to form the thick gate insulating film in the peripheral circuit region 12, wet etching is performed after completion of H₂ baking in (b) of FIG. 5D. Then, in the state where the diffusion layer regions 2a and 2b are exposed in both of the memory cell region 11 and the peripheral circuit region 12, the new gate insulating films 3a and 3b are formed.

As the gate insulating films 13a and 13b and the new gate insulating films 3a and 3b, a silicon oxide film (SiO₂), a laminated film comprising a silicon oxide film and a nitride film (Si₃N₄), or any other insulating film having a high dielectric constant may be used.

Subsequent steps are similar to those in the first embodiment and will not be described herein.

As described above, in the third embodiment, the diffusion layer region in the memory cell region alone can be curved. Generally, a transistor used in the memory cell region is designed so that the width of a diffusion layer region (active region) is narrowest in a product. This means that the transistor in the memory cell region is most susceptible to a decrease in on current. By the use of this invention, it is possible to suppress a decrease in on current of the transistor in the memory cell region without causing an influence to other transistors.

### Fourth Embodiment

A fourth embodiment of this invention is another modification of the first embodiment. In the fourth embodiment, H₂ baking is performed after epitaxial growth is carried out only in a memory cell region.

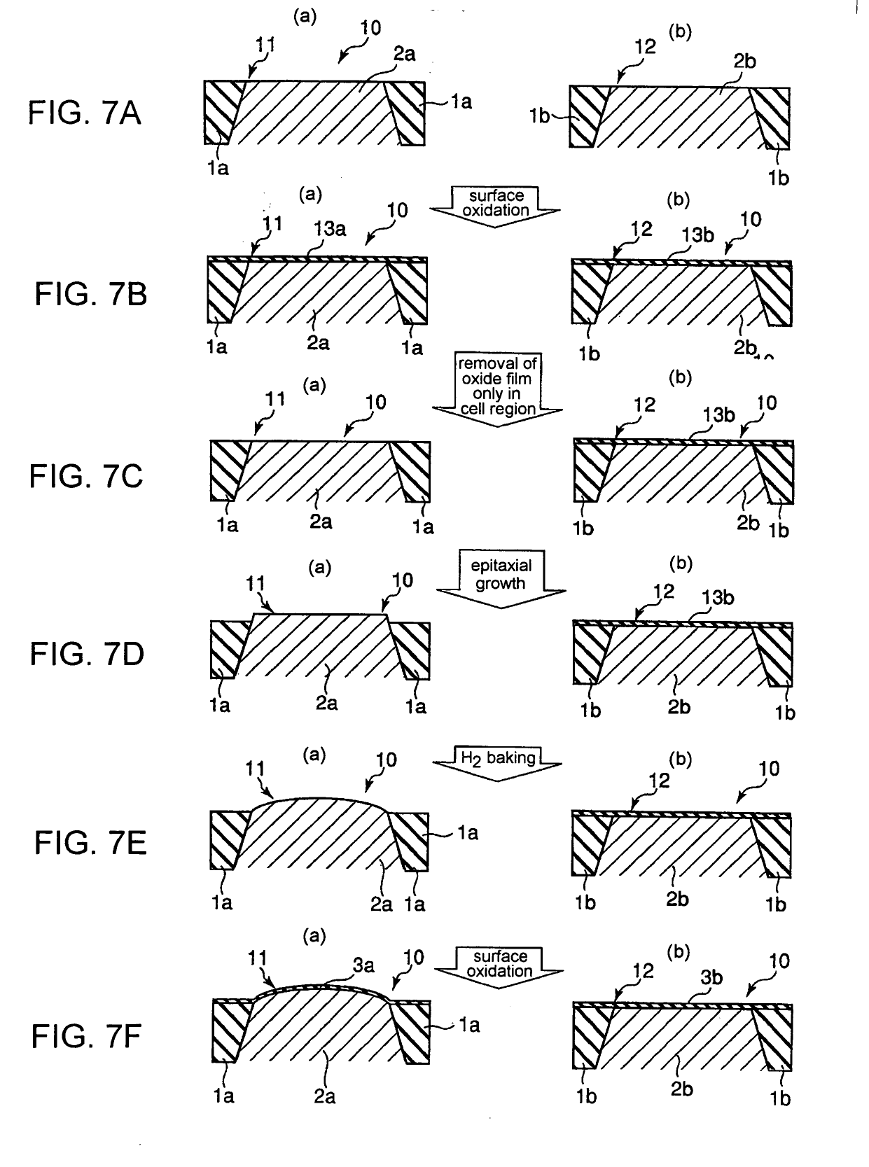

In FIGS. 7A to 7F, (a) shows a thin film part of a gate insulating film to which a method according to the fourth embodiment is applied. (b) shows a thick film part of the gate insulating film corresponding to (a).

At first, as illustrated in FIG. 7A, device isolation regions 1a and 1b are formed on a semiconductor substrate made of silicon by the use of STI as a known technique, respectively. Remaining parts except the device isolation regions 1a and 1b are diffusion layer regions 2a and 2b.

Next, as illustrated in FIG. 7B, gate insulating films 13a and 13b are formed on the diffusion regions 2a and 2b by a known technique, respectively.

As illustrated in (a) in FIG. 7C. the gate insulating film 13a is removed by wet etching only in a memory cell region 11 to expose the diffusion layer region 2a. On the other hand, as illustrated in (b) in FIG. 7C, the gate insulating film 13b in a peripheral circuit region 12 is not removed. As a result, the diffusion layer region 2b is kept covered with the gate insulating film 13b. In the state where the diffusion layer region 2a is exposed and the diffusion layer region 2b is covered with the gate insulating film 13b, selective epitaxial growth of silicon is carried out. As a consequence, as illustrated in (a) of FIG. 7D, an epitaxial layer is formed on the surface of the diffusion layer region 2a. Since a surface and a side surface of the epitaxial layer are exposed, an exposed surface on the diffusion layer region 2a is increased in area.

On the other hand, the diffusion layer region 2b in the peripheral circuit region 12 is covered with the gate insulating film 13b. Therefore, no epitaxial layer of silicon is formed on the diffusion layer region 2b.

In the abovementioned state, baking is carried out in a hydrogen (H₂) atmosphere at a temperature between 800° C. and 1000° C.

As illustrated in (a) of FIG. 7E, silicon atoms exposed to the hydrogen atmosphere at a high temperature migrate so that the diffusion layer region 2a has a round shape protruding upward. On the other hand, as illustrated in (b) of FIG. 7E, the diffusion layer region 2b covered with the gate insulating film 13b maintains a flat surface.

As illustrated in (a) of FIG. 7F, a new gate insulating film 3a is formed on the diffusion layer region 2a by a known technique. As illustrated in (b) of FIG. 7F, a new gate insulating film is also formed on the gate insulating film 13b in the peripheral circuit region 12 to form a thick gate insulating film 3b. Like in the third embodiment, wet etching may be performed after H₂ baking in (b) of FIG. 7E. Then, in the state where both the diffusion layer regions 2a and 2b are exposed, new gate insulating films are formed throughout an entirety.

As the gate insulating films 13a and 13b and the new gate insulating films 3a and 3b, a silicon oxide film (SiO₂), a laminated film comprising a silicon oxide film and a nitride film (Si₃N₄), or any other insulating film having a high dielectric constant may be used.

Subsequent steps are similar to those in the first embodiment and will not be described herein.

In the fourth embodiment, as illustrated in (a) of FIG. 7D, a silicon layer is formed by selective epitaxial growth in the memory cell region prior to H₂ baking. Thus, it is possible to further enlarge a surface area of the diffusion layer region (active region) of a transistor. It is therefore possible to further increase an on current ion of a transistor in the memory cell region.

### Fifth Embodiment

In a fifth embodiment of this invention, H₂ baking is performed twice. This provides a greater difference in curving rate (protruding amount) between diffusion layer regions in a memory cell region and a peripheral circuit region.

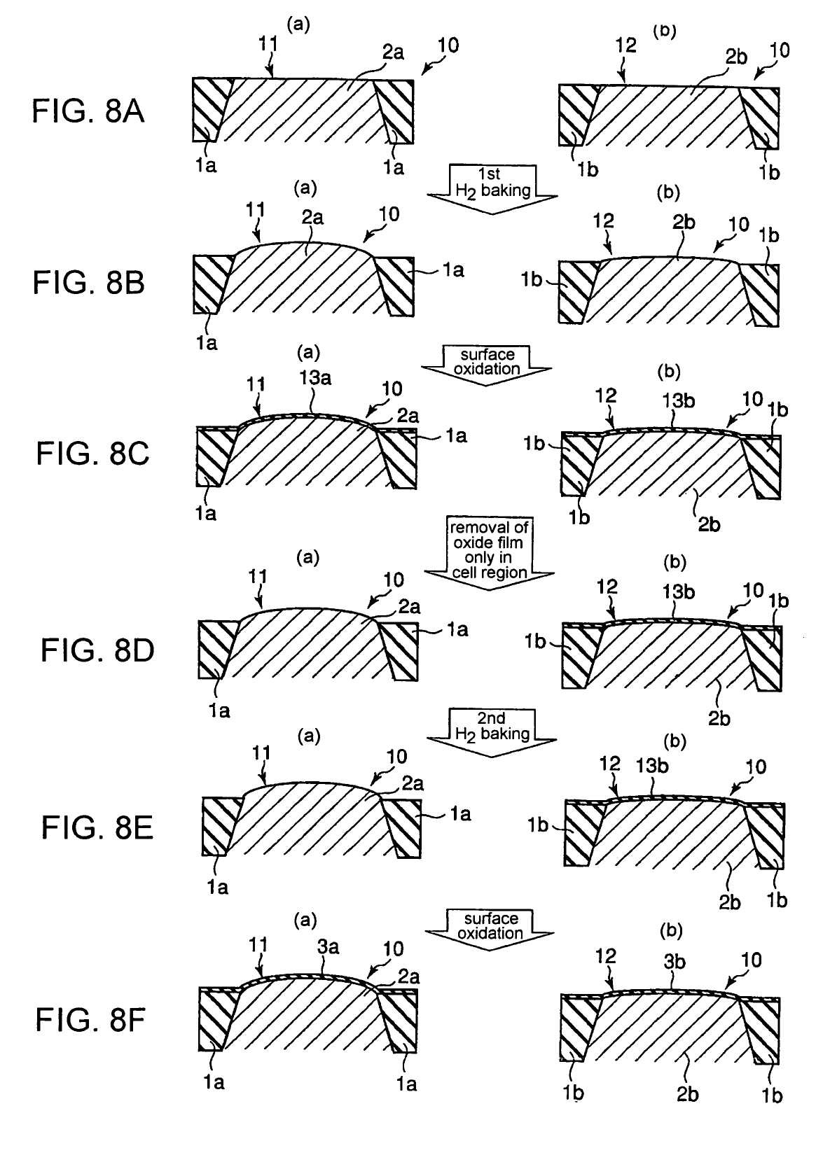

In FIGS. 8A to 8F, (a) shows a thin film part of a gate insulating film to which a method according to the fifth embodiment is applied. (b) shows a thick film part of the gate insulating film corresponding to (a).

At first, as illustrated in FIG. 8A, device isolation regions 1a and 1b are formed on a semiconductor substrate 10 made of silicon by the use of STI as a known technique, respectively. Remaining parts except the device isolation regions 1a and 1b are diffusion layer regions 2a and 2b.

Next, in the state where silicon surfaces of the diffusion layer regions 2a and 2b are exposed, first baking is carried out in a hydrogen (H₂) atmosphere at a temperature between 800° C. and 1000° C.

As illustrated in (a) of FIG. 8B, silicon atoms exposed to the hydrogen atmosphere at a high temperature migrate so that each of the diffusion layer regions 2a and 2b has a round shape protruding upward.

Next, as illustrated in FIG. 8C, gate insulating films 13a and 13b are formed on the diffusion regions 2a and 2b by a known technique, respectively.

As illustrated in (a) of FIG. 8D, the gate insulating film 13a is removed by wet etching only in a memory cell region 11 to expose the diffusion layer region 2a. On the other hand, as illustrated in (b) in FIG. 8D, the gate insulating film 13b in a peripheral circuit region 12 is not removed. As a result, the diffusion layer region 2b is kept covered with the gate insulating film 13b. In the state where the diffusion layer region 2a is exposed and the diffusion layer region 2b is covered with the gate insulating film 13b, second baking is carried out in a hydrogen (H₂) atmosphere at a temperature between 800° C. and 1000° C.

As a consequence, the diffusion layer region 2a in the memory cell region 11 has a more greatly curved shape as illustrated in (a) of FIG. 8E. On the other hand, as illustrated in (b) of FIG. 8E, the diffusion layer region 2b in the peripheral circuit region 12 maintains the curved shape after the first H₂ baking.

As illustrated in (a) of FIG. 8F, a new gate insulating film 3a is formed on the diffusion layer region 2a by a known technique. As illustrated in (b) of FIG. 8F, a new gate insulating film is also formed on the gate insulating film 13b in the peripheral circuit region 12 to form a thick gate insulating film 3b. Like in the third embodiment, wet etching may be performed after the second H₂ baking in (b) of FIG. 8E. Then, in the state where both the diffusion layer regions 2a and 2b are exposed, new gate insulating films are formed throughout an entirety.

Subsequent steps are similar to those in the first embodiment and will not be described herein.

In the fifth embodiment, the curved shape in the memory cell region 11 has a greatly curved shape as compared with the first embodiment. Therefore, it is possible to further increase an on current of a transistor.

As described above, a semiconductor apparatus and a method of producing the same according to this invention are applicable generally to semiconductor products in which an active element such as a transistor is formed on an active region (for example, a diffusion layer region).

Although this invention has been described in conjunction with a few exemplary embodiments thereof, this invention is not limited to the foregoing embodiments but may be modified in various other manners within the scope of the appended claims.

1. A semiconductor apparatus comprising a silicon substrate, a first diffusion layer region formed on the silicon substrate and comprising a plurality of diffusion layers separated by a device isolation region, and a second diffusion layer region formed on the silicon substrate at a position different from that of the first diffusion layer region and comprising a plurality of diffusion layers,
wherein the diffusion layers in the first diffusion layer region have an upwardly curved shape formed by upwardly protruding a surface of the silicon substrate, and the diffusion layers of the second diffusion layer region have a flat shape as compared with the first diffusion layer region.

2. The semiconductor apparatus as claimed in claim 1, further comprising a memory cell region in which a plurality of the first diffusion layer regions of the same shape are regularly arranged.

3. The semiconductor apparatus as claimed in claim 1, wherein the second diffusion layer region comprises a peripheral circuit region comprising a region provided with scribe lines.

4. A semiconductor apparatus comprising a silicon substrate, a first diffusion layer region formed on the silicon substrate and comprising a plurality of diffusion layers separated by a device isolation region, and a second diffusion layer region formed on the silicon substrate at a position different from that of the first diffusion layer region and comprising a plurality of diffusion layers, wherein the diffusion layers in both of the first and the second diffusion layer regions have an upwardly curved shape formed by upwardly protruding a surface of the silicon substrate, the first diffusion layer region comprising the diffusion layers smaller in radius of curvature of the surface of the silicon substrate than the diffusion layers forming the second diffusion layer region.

5. The semiconductor apparatus as claimed in claim 1, further comprising a first gate insulating film formed on the first diffusion layer region and a second gate insulating film formed on the second diffusion layer region, the first and the second gate insulating films being different in thickness.

6. The semiconductor apparatus as claimed in claim 1, further comprising gate electrodes formed on the first and the second diffusion layer regions through gate insulating films, respectively.

7. A semiconductor apparatus comprising a silicon substrate, a first diffusion layer region formed on the silicon substrate and comprising a plurality of diffusion layers separated by a device isolation region, and a second diffusion layer region formed on the silicon substrate at a position different from that of the first diffusion layer region and comprising a plurality of diffusion layers, wherein the first diffusion layer region is provided with a second silicon layer formed in contact with a surface of a first silicon layer forming the silicon substrate, the second silicon layer having a surface of an upwardly curved shape.

8. The semiconductor apparatus as claimed in claim 7, wherein the second diffusion layer region is flat as compared with the surface of the second silicon layer.

9. A semiconductor apparatus comprising a silicon substrate, and first and second diffusion layers formed on the silicon substrate, separated by a device isolation region, and having first and second widths, respectively, wherein the second width is greater than the first width, each of the first and the second diffusion layers having an upwardly curved shape formed by upwardly protruding a surface of the silicon substrate, the first diffusion layer being smaller in radius of curvature than the second diffusion layer, the radius of curvature representing a curved shape of the surface of the silicon substrate.

10. A method of producing a semiconductor apparatus, comprising forming a device isolation region on a silicon substrate to separate a plurality of diffusion layer regions, forming an insulating film on a surface of each of the diffusion layer regions, partly removing the insulating film to expose a surface of the silicon substrate at a part of each of the diffusion layer regions, and curving an exposed part of the surface of the silicon substrate into a round shape by heat treating the silicon substrate in a high-temperature hydrogen atmosphere.

11. The method as claimed in claim 10, wherein the curving comprises curving the silicon substrate upward depending upon the size of the exposed part of the surface of the silicon substrate.

12. The method as claimed in claim 10, wherein the curving the surface of the silicon substrate is followed by removing a whole of the insulating film, forming a gate insulating film throughout an entire surface of the silicon substrate, and forming a gate electrode on the gate insulating film.

13. The method as claimed in claim 10, wherein the hydrogen atmosphere has a temperature between 800° C. and 1000° C.

14. The semiconductor apparatus as claimed in claim 4, further comprising a first gate insulating film formed on the first diffusion layer region and a second gate insulating film formed on the second diffusion layer region, the first and the second gate insulating films being different in thickness.

15. The semiconductor apparatus as claimed in claim 4, further comprising gate electrodes formed on the first and the second diffusion layer regions through gate insulating films, respectively.
